(19) United States
(12) Patent Application Publication
(10) Pub. No.: US 2019/0109253 A1
(43) Pub. Date: Apr. 11, 2019

(54) SOLAR CELL AND METHOD FOR MANUFACTURING SAME, AND SOLAR CELL PANEL

(71) Applicant: KANEKA CORPORATION, Osaka (JP)

(72) Inventors: Hayato Kawasaki, Osaka (JP); Kunta Yoshikawa, Osaka (JP); Kunihiro Nakano, Osaka (JP); Katsunori Konishi, Osaka (JP)

(73) Assignee: KANEKA CORPORATION, Osaka (JP)

(21) Appl. No.: 16/197,843

(22) Filed: Nov. 21, 2018

Related U.S. Application Data
(63) Continuation of application No. PCT/JP2017/004503, filed on Feb. 8, 2017.

(30) Foreign Application Priority Data
May 23, 2016 (JP) 2016-102521

(51) Int. Cl. H01L 31/0747; H01L 31/0224; H01L 31/046; H01L 31/20; H01L 31/0216

(52) U.S. Cl. CPC H01L 31/0747; H01L 31/022425; H01L 31/02167; H01L 31/202; H01L 31/046

(57) ABSTRACT

A solar cell includes a conductive crystalline silicon substrate, a first conductive silicon layer, a second conductive silicon layer, a first intrinsic silicon layer, and a second intrinsic silicon layer. The first conductive silicon layer and the second conductive silicon layer are disposed on one principal surface of the conductive crystalline silicon substrate and are electrically insulated from each other. The second conductive silicon layer includes a first portion and a second portion, where the first portion is separated from the conductive crystalline silicon substrate by the first intrinsic silicon layer and the first conductive silicon layer, and where the second portion is separated from the conductive crystalline silicon substrate by the second intrinsic silicon layer. The first intrinsic silicon layer has a greater thickness than the second intrinsic silicon layer.

### TECHNICAL FIELD

One or more embodiments of the present invention relate a solar cell with improved open circuit voltage and fill factor, a method for manufacturing the solar cell, and a solar panel including the solar cell.

### BACKGROUND

A crystalline silicon solar cell including a crystalline silicon substrate has high photoelectric conversion efficiency. Such a crystalline silicon solar cell has already been widely used as a photovoltaic system. Many crystalline silicon solar cells that are currently on the market are double-sided electrode type solar cells. To draw a current efficiently, a double-sided electrode type solar cell has two electrodes on both sides, i.e., the light receiving side for sunlight and the back side opposite to the light receiving side. More specifically, the double-sided electrode type solar cell has a positive electrode and a negative electrode on both surfaces of a crystalline silicon substrate, respectively. With this configuration, when sunlight is incident on the light receiving surface, an electron-hole pair is created in the solar cell, and then a current is drawn through the electrodes on both surfaces.

However, in the double-sided electrode type solar cell, the electrode is provided on the light receiving surface as well as the back surface to draw a current efficiently. The electrode on the light receiving surface can block the sunlight and reduce the photoelectric conversion efficiency. Therefore, a back-surface electrode type solar cell has been proposed. The back-surface electrode type solar cell includes a p-type semiconductor layer and an n-type semiconductor layer that are formed on the back surface of a crystalline silicon substrate, and electrodes provided on these semiconductor layers. Since there is no need to provide an electrode on the light receiving surface, the back-surface electrode type solar cell can improve the light receiving rate of sunlight and achieve higher photoelectric conversion efficiency.

In the back-surface electrode type solar cell, the p-type semiconductor layer and the n-type semiconductor layer should be formed on the back surface of the crystalline silicon substrate.

For example, Patent Document 1 discloses a method that includes the following: forming an intrinsic semiconductor layer, a first conductive semiconductor layer, and an insulating layer in this order on a semiconductor substrate; removing a part of the insulating layer by etching; removing the first conductive semiconductor layer and the intrinsic semiconductor layer by etching using the remaining insulating layer as a mask; and exposing a part of the crystalline silicon substrate (see FIGS. 4 to 7 of Patent Document 1).

### Patent Document

Patent Document 1: JP 2012-28718 A

However, as disclosed in Patent Document 1, when a p-type silicon layer is formed as the first conductive semiconductor layer on the semiconductor substrate, a silicon oxide layer is formed as the insulating layer on the p-type silicon layer, and then the p-type silicon layer is patterned by etching, the patterning accuracy of the p-type silicon layer is not necessarily high, so that the p-type silicon layer is largely removed due to patterning. Thus, the semiconductor substrate is exposed beyond the expected region, and the open circuit voltage and fill factor of the solar cell are reduced. Moreover, if a pin hole is present in the insulating layer, the above method cannot remove the pin hole in the middle of the process. Consequently, a leak current through the pin hole also causes a reduction in the fill factor of the solar cell.

### SUMMARY

One or more embodiments of the present invention provide a solar cell with improved open circuit voltage and fill factor, a method for manufacturing the solar cell, and a solar panel including the solar cell.

A solar cell of one or more embodiments of the present invention includes a conductive crystalline silicon substrate, and a first conductive silicon layer and a second conductive silicon layer that are disposed on one principal surface of the conductive crystalline silicon substrate. The first conductive silicon layer and the second conductive silicon layer are electrically insulated from each other. The second conductive silicon layer includes a first portion and a second portion. The first portion of the second conductive silicon layer faces the conductive crystalline silicon substrate via a first intrinsic silicon layer and the first conductive silicon layer. The second portion of the second conductive silicon layer faces the conductive crystalline silicon substrate via a second intrinsic silicon layer. A thickness of the first intrinsic silicon layer is larger than that of the second intrinsic silicon layer.

A solar panel of one or more embodiments of the present invention includes a plurality of the solar cells of one or more embodiments of the present invention.

A method for manufacturing the solar cell of one or more embodiments of the present invention includes the following: a first step of forming a first conductive silicon layer on one principal surface of a conductive crystalline silicon substrate; a second step of forming an intrinsic silicon layer A on the first conductive silicon layer formed; a third step of forming a resist film on the intrinsic silicon layer A formed; a fourth step of removing a part of the resist film formed; and a fifth step of patterning the intrinsic silicon layer A and the first conductive silicon layer by using the remaining resist film as a mask.

One or more embodiments of the present invention can provide a solar cell and a solar panel with improved open circuit voltage and fill factor.

### BRIEF DESCRIPTION OF DRAWINGS

FIG. 1 is a schematic plan view showing an example of a solar cell.

FIG. 2 is a schematic cross-sectional view showing the main portion of the solar cell, taken along the line I-I in FIG. 1.

FIGS. 3A to 3I are schematic cross-sectional views showing an example of the main portion of a manufacturing process of a solar cell.

### DETAILED DESCRIPTION OF THE EMBODIMENTS

(Embodiments of Solar Cell and Solar Panel)

First, a solar cell of one or more embodiments of the present invention will be described. The solar cell of one or more embodiments includes a conductive crystalline silicon substrate, and a first conductive silicon layer and a second conductive silicon layer that are disposed on one principal surface of the conductive crystalline silicon substrate. The first conductive silicon layer and the second conductive silicon layer are electrically insulated from each other. The second conductive silicon layer includes a first portion and a second portion. The first portion of the second conductive silicon layer faces the conductive crystalline silicon substrate via a first intrinsic silicon layer and the first conductive silicon layer. The second portion of the second conductive silicon layer faces the conductive crystalline silicon substrate via a second intrinsic silicon layer. The thickness of the first intrinsic silicon layer is larger than that of the second intrinsic silicon layer.

In the solar cell of one or more embodiments, since the first intrinsic silicon layer is thicker than the second intrinsic silicon layer, the patterning accuracy of the first conductive silicon layer is improved, and thus the open circuit voltage and fill factor of the solar cell can be improved compared to the conventional back-surface electrode type solar cell, which will be described in detail later in a method for manufacturing a solar cell of one or more embodiments of the present invention.

In the solar cell of one or more embodiments, it is preferable that an insulating layer is provided between the first intrinsic silicon layer and the first conductive silicon layer. This configuration can improve the insulation properties between the first conductive silicon layer and the second conductive silicon layer. Moreover, the first intrinsic silicon layer may include a first intrinsic silicon lower layer that is in contact with the insulating layer, and a first intrinsic silicon upper layer that is in contact with the second conductive silicon layer. With this configuration, even if a pin hole is present in the insulating layer, the first intrinsic silicon lower layer can fill the pin hole during the manufacturing process of the solar cell, and therefore can suppress a reduction in the fill factor of the solar cell due to a leak current through the pin hole.

In the solar cell of one or more embodiments, it is preferable that the first conductive silicon layer is a first conductive amorphous silicon layer and the second conductive silicon layer is a second conductive amorphous silicon layer. This configuration can reduce the occurrence of cracks in the bonding surfaces of the first conductive silicon layer and the second conductive silicon layer with other layers or the substrate, resulting in high photoelectric conversion efficiency of the solar cell.

In the solar cell of one or more embodiments, it is preferable that the first intrinsic silicon layer is a first intrinsic amorphous silicon layer and the second intrinsic silicon layer is a second intrinsic amorphous silicon layer. With this configuration, the solar cell can be manufactured by a general method for manufacturing a semiconductor.

In one or more embodiments, the conductive crystalline silicon substrate may be a conductive monocrystalline silicon substrate or a conductive polycrystalline silicon substrate. The use of the conductive monocrystalline silicon substrate can achieve higher photoelectric conversion efficiency. The use of the conductive polycrystalline silicon substrate can produce a solar cell at a lower cost.

In one or more embodiments, a third intrinsic silicon layer is preferably provided between the first conductive silicon layer and the conductive crystalline silicon substrate. In general, the surface of the conductive crystalline silicon substrate has a textured structure to reduce the reflectance of this surface for sunlight. The presence of the third intrinsic silicon layer between the first conductive silicon layer and the conductive crystalline silicon substrate strengthens the bonding between the first conductive silicon layer and the conductive crystalline silicon substrate.

In one or more embodiments, it is preferable that the third intrinsic silicon layer is a third intrinsic amorphous silicon layer. With this configuration, the solar cell can be manufactured by a general method for manufacturing a semiconductor.

The solar cell of one or more embodiments includes a first electrode that is connected to the first conductive silicon layer and a second electrode that is connected to the second conductive silicon layer. Thus, a current can be drawn from the solar cell. The first electrode may be composed of a first lower electrode that is in contact with the first conductive silicon layer and a first upper electrode that is disposed on the first lower electrode. The second electrode may be composed of a second lower electrode that is in contact with the second conductive silicon layer and a second upper electrode that is disposed on the second lower electrode.

Next, a solar panel of one or more embodiments of the present invention will be described. The solar panel of one or more embodiments includes a plurality of the solar cells of the above embodiments. The solar panel of one or more embodiments is in the form of a module including a plurality of single cells (solar cells), each of which includes a conductive crystalline silicon substrate, and a first conductive silicon layer and a second conductive silicon layer that are disposed on one principal surface of the conductive crystalline silicon substrate. The module can increase the light receiving area for sunlight and therefore can enhance the light receiving rate of sunlight. Moreover, the module has the advantage of being able to freely change the size of the solar panel in accordance with the scale of power generation and to efficiently utilize the space where the solar cells are to be installed.

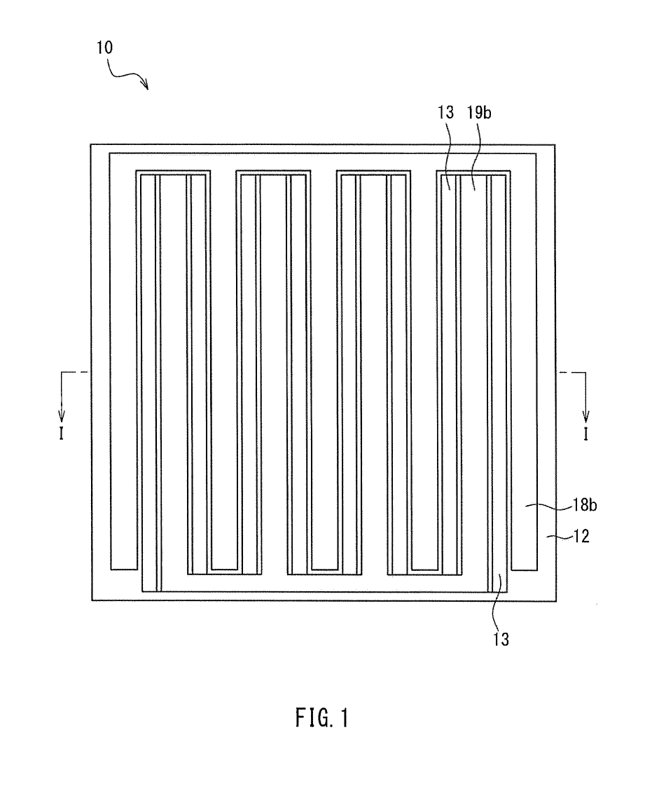

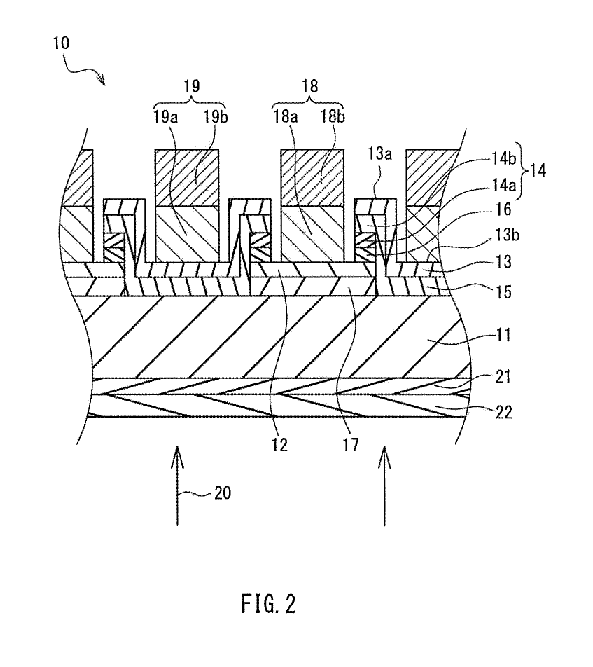

Next, the solar cell of one or more embodiments will be described with reference to the drawings. FIG. 1 is a schematic plan view showing an example of the solar cell of one or more embodiments. FIG. 2 is a schematic cross-sectional view showing the main portion of the solar cell, taken along the line I-I in FIG. 1.

In FIGS. 1 and 2, a solar cell 10 of one or more embodiments includes a conductive crystalline silicon substrate 11, and a first conductive silicon layer 12 and a second conductive silicon layer 13 that are disposed on one principal surface (back surface) of the conductive crystalline silicon substrate 11. The first conductive silicon layer 12 and the second conductive silicon layer 13 are electrically insulated from each other.

In one or more embodiments, the second conductive silicon layer 13 includes a first portion 13a and a second portion 13b. The first portion 13a faces the conductive crystalline silicon substrate 11 via a first intrinsic silicon layer 14, an insulating layer 16, the first conductive silicon layer 12, and a third intrinsic silicon layer 17. The second portion 13b faces the conductive crystalline silicon substrate 11 via a second intrinsic silicon layer 15. Moreover, the first intrinsic silicon layer 14 includes a first intrinsic silicon lower layer 14a that is in contact with the insulating layer 16, and a first intrinsic silicon upper layer 14b that is in contact with the second conductive silicon layer 13. The thickness of the first intrinsic silicon layer 14 is larger than that of the second intrinsic silicon layer 15.

In one or more embodiments, the solar cell 10 includes a first electrode 18 that is connected to the first conductive silicon layer 12 and a second electrode 19 that is connected to the second conductive silicon layer 13. The first electrode 18 is composed of a first lower electrode 18a that is in contact with the first conductive silicon layer 12 and a first upper electrode 18b that is disposed on the first lower electrode 18a. The second electrode 19 is composed of a second lower electrode 19a that is in contact with the second conductive silicon layer 13 and a second upper electrode 19b that is disposed on the second lower electrode 19a.

The solar cell 10 includes a fourth intrinsic silicon layer 21 and a protective layer 22 that are disposed on the other principal surface (light receiving surface) of the conductive crystalline silicon substrate 11. The solar cell 10 receives sunlight 20 from the light receiving surface. In the solar cell 10, no electrode is formed on the light receiving side of the conductive crystalline silicon substrate 11. Therefore, nothing blocks the sunlight from reaching the light receiving surface, so that the photoelectric conversion efficiency is improved.

In one or more embodiments, the conductive crystalline silicon substrate 11 may be an n-type monocrystalline silicon substrate or an n-type polycrystalline silicon substrate. The first conductive silicon layer 12 may be a p-type or n-type amorphous silicon layer. The second conductive silicon layer 13 may be a p-type or n-type amorphous silicon layer that has a different conductivity type from the first conductive silicon layer 12. Each of the first intrinsic silicon layer 14, the second intrinsic silicon layer 15, the third intrinsic silicon layer 17, and the fourth intrinsic silicon layer 21 may be formed of an intrinsic amorphous silicon layer. The insulating layer 16 and the protective layer 22 may be made of silicon oxide, silicon nitride, silicon oxynitride, or a laminated material thereof.

(Methods for Manufacturing a Solar Cell)

Next, a method for manufacturing a solar cell of one or more embodiments of the present invention will be described. The method for manufacturing the solar cell of one or more embodiments includes the following: a first step of forming a first conductive silicon layer on one principal surface of a conductive crystalline silicon substrate; a second step of forming an intrinsic silicon layer A on the first conductive silicon layer formed; a third step of forming a resist film on the intrinsic silicon layer A formed; a fourth step of removing a part of the resist film formed; and a fifth step of patterning the intrinsic silicon layer A and the first conductive silicon layer by using the remaining resist film as a mask.

The method for manufacturing the solar cell of one or more embodiments includes the second step of forming the intrinsic silicon layer A on the first conductive silicon layer formed, and thus improves the patterning accuracy of the first conductive silicon layer. Accordingly, the open circuit voltage and fill factor of the solar cell can be improved compared to the conventional back-surface electrode type solar cell. In other words, since the intrinsic silicon layer A is formed on the first conductive silicon layer in the second step of the manufacturing method of one or more embodiments, when a part of the resist film is removed by exposure to ultraviolet light or the like in the fourth step, the intrinsic silicon layer A can absorb the ultraviolet light or the like that has passed through the resist film. Therefore, the patterning of an unexpected region of the first conductive silicon layer can be suppressed, thereby improving the patterning accuracy of the first conductive silicon layer.

In one or more embodiments, it is preferable that an insulating layer is formed on the first conductive silicon layer formed and then the intrinsic silicon layer A is formed on the insulating layer in the second step, and that the intrinsic silicon layer A, the insulating layer, and the first conductive silicon layer are patterned by using the remaining resist film as a mask in the fifth step. This process can improve the insulation properties between the first conductive silicon layer and the second conductive silicon layer. Moreover, since the intrinsic silicon layer A is formed on the insulating layer, even if a pin hole is present in the insulating layer, the intrinsic silicon layer A can fill the pin hole, and therefore can suppress a reduction in the fill factor of the solar cell due to a leak current through the pin hole.

In one or more embodiments, it is preferable that an intrinsic silicon layer B is formed on one principal surface of the conductive crystalline silicon substrate and then the first conductive silicon layer is formed on the intrinsic silicon layer B in the first step, and that the intrinsic silicon layer A, the first conductive silicon layer, and the intrinsic silicon layer B are patterned by using the remaining resist film as a mask in the fifth step. In general, the surface of the conductive crystalline silicon substrate has a textured structure to reduce the reflectance of this surface for sunlight. The presence of the intrinsic silicon layer B on the conductive crystalline silicon substrate strengthens the bonding between the first conductive silicon layer and the conductive crystalline silicon substrate.

In one or more embodiments, it is more preferable that an intrinsic silicon layer B is formed on one principal surface of the conductive crystalline silicon substrate and then the first conductive silicon layer is formed on the intrinsic silicon layer B in the first step, that an insulating layer is formed on the first conductive silicon layer formed and then the intrinsic silicon layer A is formed on the insulating layer in the second step, and that the intrinsic silicon layer A, the insulating layer, the first conductive silicon layer, and the intrinsic silicon layer B are patterned by using the remaining resist film as a mask in the fifth step.

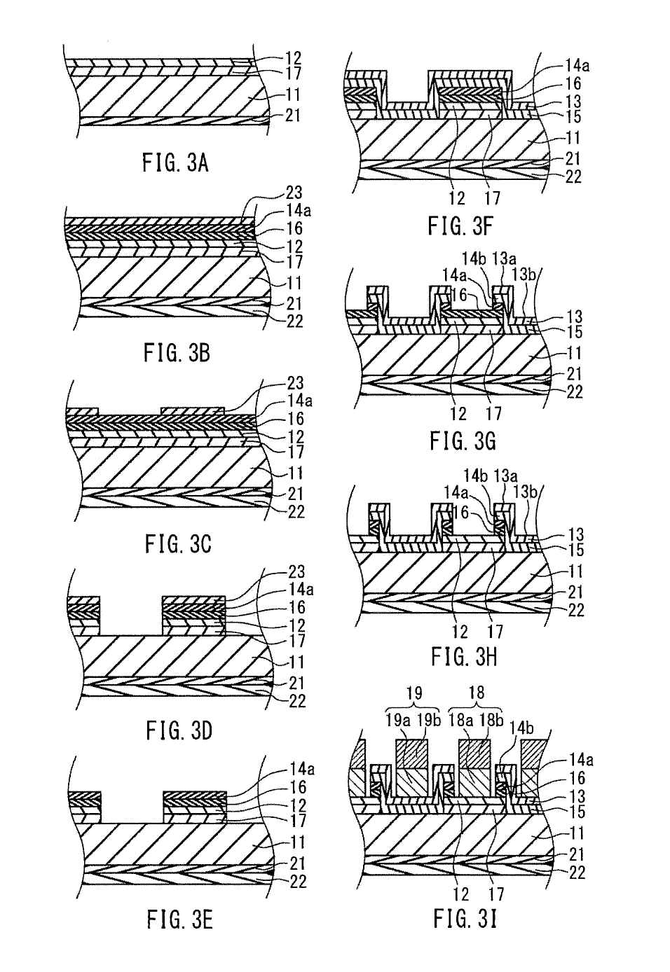

Next, the method for manufacturing the solar cell of one or more embodiments will be described based on the drawings. FIG. 3 is a schematic cross-sectional view showing an example of the main portion of the manufacturing process of the solar cell of one or more embodiments. In FIG. 3, the members corresponding to those shown in FIG. 2 are denoted by the same reference numerals as in FIG. 2.

First, as shown in FIG. 3A, an intrinsic silicon layer 21 is formed on substantially the entire surface of the principal surface on the light receiving side of an n-type crystalline silicon substrate 11, and an intrinsic silicon layer 17 is formed on substantially the entire surface of the principal surface on the back side of the n-type crystalline silicon substrate 11. The surface passivation effect can be expected by the formation of the intrinsic silicon layer 17. In this case, the term “substantially the entire surface” means at least 90% of the principal surface. In one or more embodiments, the intrinsic silicon layer is preferably formed on the entire surface of the n-type crystalline silicon substrate 11 except for regions with minimum areas such as pin holes and irregularities in the film at the edges of the substrate caused by, e.g., discharge anomaly during the film formation. The intrinsic silicon layer may be more preferably formed on at least 95% of the principal surface, and particularly preferably formed on 100% of the principal surface, i.e., the entire surface of the n-type crystalline silicon substrate 11. Although not shown in FIG. 3A, both principal surfaces of the n-type crystalline silicon substrate 11 have a textured structure from the viewpoint of improving the light capture efficiency due to the light trapping effect. Subsequently, a p-type silicon layer 12 is formed to substantially cover the intrinsic silicon layer 17.

In one or more embodiments, it is preferable that the intrinsic silicon layer 21, the intrinsic silicon layer 17, and the p-type silicon layer 12 are formed by a plasma CVD method. When the plasma CVD method is used to form the silicon layers, the film quality can be relatively easily controlled in accordance with the film formation conditions. This makes it easy to adjust the etchant resistance or the refractive index.

In one or more embodiments, preferred conditions for the formation of the silicon layers by the plasma CVD method are as follows: the substrate temperature is 100 to 300° C.; the pressure is 20 to 2600 Pa; and the high-frequency power density is 0.004 to 0.8 W/cm². The source gas used for forming the silicon layers may be preferably, e.g., silicon containing gas such as SiH₄ and Si₂H₆ or mixed gas of silicon-based gas and H₂.

Next, as shown in FIG. 3B, a protective layer 22 is formed on the intrinsic silicon layer 21, and an insulating layer 16 is formed on the p-type silicon layer 12. Both the protective layer 22 and the insulating layer 16 may be preferably made of silicon oxide, silicon nitride, silicon oxynitride, or a laminated material thereof. In one or more embodiments, it is preferable that the protective layer 22 and the insulating layer 16 are also formed by the plasma CVD method.

Then, an intrinsic silicon layer 14a is formed on the insulating layer 16, and a photoresist 23 is further formed on the intrinsic silicon layer 14a. In one or more embodiments, it is preferable that the intrinsic silicon layer 14a is also formed by the plasma CVD method. The photoresist 23 may be either positive or negative and may be preferably a positive photoresist because of ease of availability of materials and high patterning accuracy. One or more embodiments use the positive photoresist in the following.

Next, as shown in FIG. 3C, a part of the photoresist 23 is removed by exposure using a photomask (not shown) for forming a pattern of the p-type silicon layer 12 so that a part of the intrinsic silicon layer 14a is exposed.

Next, as shown in FIG. 3D, parts of the intrinsic silicon layer 14a, the insulating layer 16, the p-type silicon layer 12, and the intrinsic silicon layer 17 are etched by using the photoresist 23 as a mask. In this case, the etchant may be preferably an acid solution containing hydrogen fluoride. The etchants suitable for each of the layers may be appropriately selected.

The method for manufacturing the solar cell of one or more embodiments includes the step of forming the intrinsic silicon layer 14a on the insulating layer 16. Therefore, when the photoresist 23 is, e.g., positive and a part of the photoresist 23 is removed by exposure to ultraviolet light or the like, the intrinsic silicon layer 14a absorbs the ultraviolet light or the like that has passed through the photoresist 23, and thus can suppress reflection and scattering of the ultraviolet light or the like from the insulating layer 16 or the n-type crystalline silicon substrate 11 having a textured structure. This can prevent the photoresist 23 from being excessively exposed to the reflected and scattered ultraviolet light or the like. Therefore, the photoresist 23 can be removed according to the designed pattern to form a mask, so that the patterning of an unexpected region can be suppressed. Consequently, the p-type silicon layer 12 can be etched according to the designed pattern, thereby improving the patterning accuracy of the p-type silicon layer 12.

As described above, since reflection and scattering of the ultraviolet light or the like can be suppressed during exposure, both principal surfaces of the n-type crystalline silicon substrate 11 can have a textured structure, which improves the light trapping effect and further increases the surface area of the n-type crystalline silicon substrate 11. Thus, the electrode area can be increased to reduce contact resistance, so that the solar cell with higher efficiency can be manufactured.

In one or more embodiments the intrinsic silicon layer 14a also functions as the insulating layer. Therefore, even if a pin hole is present in the insulating layer 16, the intrinsic silicon layer 14a can fill the pin hole, and the insulation properties can be improved.

Moreover, the refractive index of the intrinsic silicon layer 14a formed on the insulating layer 16 is lower than that of the insulating layer 16 made of, e.g., silicon oxide, silicon nitride, or silicon oxynitride. Such a difference in the refractive index between the intrinsic silicon layer 14a and the insulating layer 16 makes the intrinsic silicon layer 14a look white, and thus facilitates visual identification of the region where the insulating layer 16 is formed for patterning. This can improve the workability in the manufacturing process of the solar cell.

On the other hand, the conventional method for manufacturing the solar cell does not include a step of forming the intrinsic silicon layer 14a. Therefore, when the photoresist is, e.g., positive and a part of the photoresist is removed by exposure to ultraviolet light or the like, the ultraviolet light or the like that has passed through the photoresist is reflected and scattered from the insulating layer or the n-type crystalline silicon substrate having a textured structure. As a result, the exposed region of the photoresist is larger than designed due to the reflected and scattered ultraviolet light or the like. Therefore, the photoresist cannot be removed according to the designed pattern to form a mask, so that an unexpected region will be etched, leading to poor performance of the solar cell. In light of this, a mask may be designed to have a margin beforehand. However, it is difficult to control broadening of the region of the photoresist that is to be exposed to the reflected and scattered ultraviolet light or the like. For this reason, a sufficient margin should be maintained. The region with a margin eventually becomes an insulating region. Thus, the region that does not contribute to power generation is increased, which also leads to poor performance of the solar cell.

As described above, the method for manufacturing the solar cell of one or more embodiments includes the step of forming the intrinsic silicon layer 14a on the insulating layer 16. The intrinsic silicon layer 14a may have any thickness as long as it can absorb the ultraviolet light or the like. The thickness of the intrinsic silicon layer 14a may be preferably 5 to 20 nm with respect to the direction perpendicular to the n-type crystalline silicon substrate 11, and more preferably 12 to 20 nm in order for the intrinsic silicon layer 14a to eventually function as an insulating layer.

Next, as shown in FIG. 3E, the photoresist is peeled off. Consequently, the steps shown in FIGS. 3A to 3E provide a region with the p-type silicon layer in which the p-type silicon layer 12 is formed, and a region without the p-type silicon layer in which the p-type silicon layer has been etched and the n-type crystalline silicon substrate 11 is exposed.

Next, as shown in FIG. 3F, an intrinsic silicon layer 15 is formed to substantially cover the region with the p-type silicon layer and the region without the p-type silicon layer. Further, an n-type silicon layer 13 is formed to substantially cover the intrinsic silicon layer 15. In one or more embodiments, it is preferable that the intrinsic silicon layer 15 and the n-type silicon layer 13 are formed by the plasma CVD method. In FIG. 3F, the intrinsic silicon layer 17, the p-type silicon layer 12, the insulating layer 16, and the intrinsic silicon layer 14a are formed in the region with the p-type silicon layer. In this case, the substrate may be preferably cleaned before the step of forming the intrinsic silicon layer 15 and the n-type silicon layer 13, and more preferably cleaned with a hydrogen fluoride aqueous solution.

Next, as shown in FIG. 3G, parts of the n-type silicon layer 13, the intrinsic silicon layer 15, and the intrinsic silicon layer 14a that are formed on the insulating layer 16 are removed by etching to expose the surface of the insulating layer 16. In FIG. 3G, the n-type silicon layer 13, the intrinsic silicon layer 14b (15), and the intrinsic silicon layer 14a are formed on a part of the insulating layer 16. The n-type silicon layer 13 includes a first portion 13a and a second portion 13b. A part of the first portion 13a faces the n-type crystalline silicon substrate 11 via the intrinsic silicon layer 14b, the intrinsic silicon layer 14a, the insulating layer 16, the p-type silicon layer 12, and the intrinsic silicon layer 17. The second portion 13b faces the n-type crystalline silicon substrate 11 via the intrinsic silicon layer 15.

Next, as shown in FIG. 3H, the insulating layer 16 in the exposed region is removed by etching. Finally, as shown in FIG. 3I, a first electrode 18 is formed on the p-type silicon layer 12 and a second electrode 19 is formed on the n-type silicon layer 13. The first electrode 18 is composed of a first lower electrode 18a and a first upper electrode 18b. The second electrode 19 is composed of a second lower electrode 19a and a second upper electrode 19b. The method for forming the first lower electrode 18a and the second lower electrode 19a is not particularly limited. For example, these electrodes may be formed by a physical vapor phase deposition method such as sputtering or a chemical vapor phase deposition method using the reaction between an organometallic compound and oxygen or water. Moreover, the method for forming the first upper electrode 18b and the second upper electrode 19b is not particularly limited. For example, these electrodes may be formed by applying a conductive paste with a printing process.

As a result of the above steps, the back-surface electrode type solar cell of one or more embodiments is completed. In the solar cell of one or more embodiments, as shown in FIG. 3I, the thickness of the layer including the intrinsic silicon layer 14a and the intrinsic silicon layer 14b is larger than that of the intrinsic silicon layer 15.

### EXAMPLES

Hereinafter, one or more embodiments of the present invention will be described in detail by way of examples. However, embodiments of the present invention are not limited to the following examples.

### Example 1

A back-surface electrode type solar cell as shown in FIG. 2 was manufactured by the steps as shown in FIG. 3.

First, an n-type monocrystalline silicon substrate 11 was prepared, which had the plane of incidence in the direction of (100) and a thickness of 200 μm. This substrate was immersed in 2% by mass of a hydrogen fluoride aqueous solution for 3 minutes so that the silicon oxide film on the surface was removed. Then, the substrate was washed two times with ultrapure water. A mixed aqueous solution containing 5% by mass of KOH and 15% by mass of isopropyl alcohol was maintained at 70° C. The above substrate was immersed in the mixed aqueous solution for 15 minutes so that the surface of the substrate was etched to form a texture. Then, the substrate was washed two times with ultrapure water. At this stage, the surface of the n-type monocrystalline silicon substrate was observed with an atomic force microscope (AFM) manufactured by Pacific Nanotechnology, Inc. The observation confirmed that the etching on the surface of the substrate proceeded most rapidly, and the (111) plane was exposed to form a pyramidal texture.

Next, the etched substrate was introduced into a CVD apparatus. Then, intrinsic amorphous silicon (i.e., the intrinsic silicon layer 21) with a thickness of 10 nm was formed on the light receiving surface (second principal surface) of the n-type monocrystalline silicon substrate 11. The intrinsic amorphous silicon was formed under the following conditions: the substrate temperature was 150° C.; the pressure was 120 Pa; the SiH₄/H₂ flow rate ratio was 3/10; and the input power density was 0.011 W/cm². The thickness of the thin film in this example was calculated from the film formation rate that was determined using a spectroscopic ellipsometry (trade name: M2000, manufactured by J. A. Woollam Co., Inc.) to measure the thickness of a thin film formed on a glass substrate under the same conditions.

Similarly, intrinsic amorphous silicon (i.e., the intrinsic silicon layer 17) with a thickness of 8 nm was formed on the back surface (first principal surface) of the n-type monocrystalline silicon substrate 11 by a CVD method. Then, p-type amorphous silicon (i.e., the p-type silicon layer 12) with a thickness of 7 nm was formed on the intrinsic silicon layer 17. The p-type amorphous silicon was formed under the following conditions: the substrate temperature was 150° C.; the pressure was 60 Pa; the SiH₄/B₂H₆ flow rate ratio was 1/3; and the input power density was 0.01 W/cm². The B₂H₆ gas flow rate was the flow rate of diluent gas obtained by diluting the B₂H₆ gas with H₂ until the B₂H₆ concentration was 5000 ppm.

Next, silicon nitride (i.e., the protective layer 22 on the light receiving side) with a thickness of 70 nm was formed on the intrinsic silicon layer 21 by the CVD method. The silicon nitride was formed under the following conditions: the substrate temperature was 140° C.; the pressure was 80 Pa; the SiH₄/NH₃ flow rate ratio was 1/4; and the input power density was 0.2 W/cm². Subsequently, silicon oxide (i.e., the insulating layer 16) with a thickness of 260 nm was formed on the p-type silicon layer 12 by the CVD method. Further, intrinsic amorphous silicon (i.e., the intrinsic silicon layer 14a) with a thickness of 14 nm was formed on the insulating layer 16 by the CVD method. The silicon oxide was formed under the following conditions: the substrate temperature was 150° C.; the pressure was 60 Pa; the SiH₄/CO₂ flow rate ratio was 1/40; and the input power density was 0.04 W/cm². The intrinsic amorphous silicon was formed under the following conditions: the substrate temperature was 150° C.; the pressure was 60 Pa; the SiH₄/CO₂ flow rate ratio was 1/40; and the input power density was 0.04 W/cm².

The photoresist 23 was formed to substantially cover the intrinsic silicon layer 14a. Then, a part of the photoresist 23 was exposed to ultraviolet light using a photomask, developed by a KOH aqueous solution, and removed to expose the intrinsic silicon layer 14a.

Next, using the remaining photoresist 23 as a mask, a part of the intrinsic silicon layer 14a was removed by etching with a KOH aqueous solution, and then a part of the insulating layer 16 was removed by etching with an HF aqueous solution. Further, the p-type silicon layer 12 and the intrinsic silicon layer 17 were etched with a mixed acid of HF and HNO₃, thereby exposing the first principal surface of the n-type monocrystalline silicon substrate 11. Subsequently, the photoresist 23 was peeled off and removed by using a mixed organic solvent of ethanol, acetone, and isopropyl alcohol.

Next, the substrate contaminated by etching was washed with an HF aqueous solution and introduced into the CVD apparatus. Then, intrinsic amorphous silicon (i.e., the intrinsic silicon layer 15) with a thickness of 8 nm was formed on the first principal surface. The intrinsic amorphous silicon was formed under the following conditions: the substrate temperature was 150° C.; the pressure was 120 Pa; the SiH₄/H₂ flow rate ratio was 3/10; and the input power density was 0.011 W/cm².

Next, n-type amorphous silicon (i.e., the n-type silicon layer 13) with a thickness of 12 nm was formed on the intrinsic silicon layer 15. The n-type amorphous silicon was formed under the following conditions: the substrate temperature was 150° C.; the pressure was 60 Pa; the SiH₄/PH₃ flow rate ratio was 1/3; and the input power density was 0.01 W/cm². The PH₃ gas flow rate was the flow rate of diluent gas obtained by diluting the PH₃ gas with H₂ until the PH₃ concentration was 5000 ppm.

Parts of the n-type silicon layer 13, the intrinsic silicon layer 15, and the intrinsic silicon layer 14a that were formed on the insulating layer 16 were etched with a KOH aqueous solution, and then the insulating layer 16 was removed by etching with an HF aqueous solution to expose the surface of the p-type silicon layer 12.

Next, indium tin oxide (ITO, refractive index: 1.9) with a thickness of 50 nm was formed by sputtering on substantially the entire surface of the first principal surface on which the p-type silicon layer 12 and the n-type silicon layer 13 were formed. The ITO was formed as a transparent conductive film under the following conditions: indium oxide was used as a target; the substrate temperature was room temperature; the pressure was 0.2 Pa in an argon atmosphere; and the applied power density was 0.5 W/cm². A part of the transparent conductive film was removed by etching with hydrochloric acid. Then, the transparent conductive film was separated into the first lower electrode 18a and the second lower electrode 19a.

Finally, an Ag paste was applied on the first lower electrode 18a and the second lower electrode 19a by screen printing, and thus the first upper electrode 18b and the second upper electrode 19b were formed, respectively.

### Comparative Example 1

A back-surface electrode type solar cell was manufactured in the same manner as Example 1 except that the intrinsic silicon layer 14a was not formed on the insulating layer 16, and the etching step of the intrinsic silicon layer 14a was omitted.

The photoelectric conversion properties of the solar cells of Example 1 and Comparative Example 1 that were manufactured in the above manner were evaluated by measuring the open circuit voltage (V_{OC}), the short circuit current (I_{SC}), the fill factor (FF), and the conversion efficiency (Eff). Table 1 shows the results. In Table 1, the measurement results of Example 1 are expressed as a relative ratio to the corresponding values of Comparative Example 1, where each of the values is defined as 1.00.

TABLE 1

| | Voc | Isc | FF | Eff |
|---|---|---|---|---|
| Example 1 | 1.02 | 1.00 | 1.03 | 1.05 |
| Comparative | 1.00 | 1.00 | 1.00 | 1.00 |
| Example 1 | | | | |

As is evident from Table 1, the V_{OC} and the FF were improved in Example 1, in which the intrinsic silicon layer 14a was formed on the insulating layer 16, as compared to Comparative Example 1, in which the intrinsic silicon layer 14a was not formed on the insulating layer 16. The reasons for this are considered as follows. In Example 1, the scattering of ultraviolet light was suppressed to reduce the extension of the pattern during exposure. Moreover, the laminated structure of the insulating layer 16 and the intrinsic silicon layer 14a enhanced the visibility for patterning, and thus improved the alignment accuracy. Further, the laminated structure also improved the insulation effect, which in turn suppressed the leakage of current between P and N. In particular, the extension of the pattern with respect to the design value was substantially constant, i.e., about 5 to 10 μm in Example 1, while it was about 15 to 80 μm in Comparative Example 1.

It was confirmed from the results of Example 1 and Comparative Example 1 that the use of the method for manufacturing the solar cell of one or more embodiments, which includes the formation of the intrinsic silicon layer 14a on the insulating layer 16, can not only improve the patterning accuracy and prevent the exposure of the substrate, but also improve the insulation performance, the open circuit voltage, and the fill factor.

Although the disclosure has been described with respect to only a limited number of embodiments, those skilled in the art, having benefit of this disclosure, will appreciate that various other embodiments may be devised without departing from the scope of the present invention. Accordingly, the scope of the present invention should be limited only by the attached claims.

### DESCRIPTION OF REFERENCE NUMERALS

10 Solar cell
11 Conductive crystalline silicon substrate (n-type crystalline silicon substrate)
12 First conductive silicon layer (p-type silicon layer)
13 Second conductive silicon layer (n-type silicon layer)
13a First portion of second conductive silicon layer
13b Second portion of second conductive silicon layer
14 First intrinsic silicon layer
14a First intrinsic silicon lower layer (intrinsic silicon layer)
14b First intrinsic silicon upper layer
15 Second intrinsic silicon layer (first intrinsic silicon upper layer)
16 Insulating layer
17 Third intrinsic silicon layer
18 First electrode
18a First lower electrode
18b First upper electrode
19 Second electrode
19a Second lower electrode
19b Second upper electrode
20 Sunlight
21 Fourth intrinsic silicon layer
22 Protective layer
23 Photoresist

What is claimed is:

1. A solar cell, comprising:
a conductive crystalline silicon substrate;
a first conductive silicon layer;
a second conductive silicon layer;
a first intrinsic silicon layer; and
a second intrinsic silicon layer,
wherein the first conductive silicon layer and the second conductive silicon layer are disposed on one principal surface of the conductive crystalline silicon substrate,
wherein the first conductive silicon layer and the second conductive silicon layer are electrically insulated from each other,
wherein the second conductive silicon layer includes a first portion and a second portion,
wherein the first portion is separated from the conductive crystalline silicon substrate by the first intrinsic silicon layer and the first conductive silicon layer,
wherein the second portion is separated from the conductive crystalline silicon substrate by the second intrinsic silicon layer, and
wherein the first intrinsic silicon layer has a greater thickness than the second intrinsic silicon layer.

2. The solar cell according to claim 1, further comprising an insulating layer,
wherein the insulating layer is located between the first intrinsic silicon layer and the first conductive silicon layer.

3. The solar cell according to claim 2, wherein the first intrinsic silicon layer comprises a first intrinsic silicon lower layer and a first intrinsic silicon upper layer,
wherein the first intrinsic silicon lower layer is in contact with the insulating layer, and
wherein the first intrinsic silicon upper layer is in contact with the second conductive silicon layer.

4. The solar cell according to claim 1, wherein the first conductive silicon layer is a first conductive amorphous silicon layer, and
wherein the second conductive silicon layer is a second conductive amorphous silicon layer.

5. The solar cell according to claim 1, wherein the first intrinsic silicon layer is a first intrinsic amorphous silicon layer, and
wherein the second intrinsic silicon layer is a second intrinsic amorphous silicon layer.

6. The solar cell according to claim 1, wherein the conductive crystalline silicon substrate is a conductive monocrystalline silicon substrate or a conductive polycrystalline silicon substrate.

7. The solar cell according to claim 1, further comprising a third intrinsic silicon layer,
wherein the third intrinsic silicon layer is located between the first conductive silicon layer and the conductive crystalline silicon substrate.

8. The solar cell according to claim 7, wherein the third intrinsic silicon layer is a third intrinsic amorphous silicon layer.

9. The solar cell according to claim 1, further comprising a first electrode and a second electrode,
wherein the first electrode is connected to the first conductive silicon layer and
wherein the second electrode is connected to the second conductive silicon layer.

10. The solar cell according to claim 9, wherein the first electrode is composed of a first lower electrode that is in contact with the first conductive silicon layer and a first upper electrode that is disposed on the first lower electrode, and
wherein the second electrode is composed of a second lower electrode that is in contact with the second conductive silicon layer and a second upper electrode that is disposed on the second lower electrode.

11. A solar panel comprising a plurality of the solar cells according to claim 1.

12. A method for manufacturing the solar cell according to claim 1, comprising:
forming the first conductive silicon layer on one principal surface of the conductive crystalline silicon substrate;
forming the first intrinsic silicon layer on the first conductive silicon layer;
forming a resist film on the first intrinsic silicon layer;
removing a part of the resist film; and
patterning the first intrinsic silicon layer and the first conductive silicon layer by using the remaining resist film as a mask.

13. The method according to claim 12, further comprising forming an insulating layer on the first conductive silicon layer prior to forming the first intrinsic silicon layer,
wherein the first intrinsic silicon layer is formed on the insulating layer, and
wherein the insulating layer is also patterned by using the remaining resist film as a mask.

14. The method according to claim 12, further comprising forming a third intrinsic silicon layer on the one principal surface of the conductive crystalline silicon substrate prior to forming the first conductive silicon layer,
wherein the first conductive silicon layer is formed on the third intrinsic silicon layer, and
wherein the third intrinsic silicon layer is also patterned by using the remaining resist film as a mask.

15. The method according to claim 12, further comprising:
forming a third intrinsic silicon layer prior to forming the first conductive silicon layer; and
forming an insulating layer prior to forming the first intrinsic silicon layer,
wherein the third intrinsic silicon layer is formed on the one principal surface of the conductive crystalline silicon substrate,
wherein the first conductive silicon layer is formed on the third intrinsic silicon layer,
wherein the insulating layer is formed on the first conductive silicon layer formed and the first intrinsic silicon layer is formed on the insulating layer, and
wherein the insulating layer and the third intrinsic silicon layer are also patterned by using the remaining resist film as a mask.
